(19) United States
(12) Patent Application Publication
(10) Pub. No.: US 2024/0213952 A1
(43) Pub. Date: Jun. 27, 2024

(54) RESONATOR DEVICE

(71) Applicant: SEIKO EPSON CORPORATION, Tokyo (JP)

(72) Inventors: Yukihiro Hashi, Shiojiri-shi (JP); Junichi Takeuchi, Chino-shi (JP); Tomoyuki Kamakura, Matsumoto-shi (JP)

(21) Appl. No.: 18/392,809

(22) Filed: Dec. 21, 2023

(30) Foreign Application Priority Data
Dec. 26, 2022 (JP) 2022-207948

(51) Int. Cl. H03H 9/10; H03H 3/02; H03H 9/19

(52) U.S. Cl. CPC H03H 9/1021; H03H 3/02; H03H 9/19

(57) ABSTRACT

A resonator device includes: a base substrate having a first surface and a second surface in a front-to-back relationship with the first surface; a resonator element located on a first surface side of the base substrate and including a resonator substrate and an electrode terminal disposed at a base-substrate-side surface of the resonator substrate; a mounting terminal disposed at the first surface; and a metal bump disposed between the base substrate and the resonator element, the metal bump being configured to bond the base substrate and the resonator element and electrically couple the mounting terminal and the electrode terminal. A cross-sectional area of the metal bump at a bonding portion with the resonator element is 491 μm² or more and 4007 μm² or less.

The present application is based on, and claims priority from JP Application Serial Number 2022-207948, filed Dec. 26, 2022, the disclosure of which is hereby incorporated by reference herein in its entirety.

### BACKGROUND

### 1. Technical Field

The present disclosure relates to a resonator device.

### 2. Related Art

For example, JP-A-2009-206614 (PTL 1) discloses a piezoelectric resonator device in which a quartz crystal resonator element serving as a piezoelectric resonator element is supported in a cantilever manner. According to PTL 1, an ultrasonic wave is applied while a pressure is applied using a metal bump having a convex top portion to the quartz crystal resonator element, thereby bonding the quartz crystal resonator element to a junction electrode by the metal bump.

However, since a metal bump has a high elastic modulus and is hard, depending on a bonding state of the metal bump between a resonator element and a base, resonance characteristics may deteriorate due to thermal stress caused by a linear expansion coefficient difference between the resonator element and a package.

### SUMMARY

A resonator device according to an aspect of the application includes: a base substrate having a first surface and a second surface in a front-to-back relationship with the first surface; a resonator element located on a first surface side of the base substrate and including a resonator substrate and an electrode terminal disposed at a base-substrate-side surface of the resonator substrate; a mounting terminal disposed at the first surface; and a metal bump disposed between the base substrate and the resonator element, the metal bump being configured to bond the base substrate and the resonator element and electrically couple the mounting terminal and the electrode terminal. A cross-sectional area of the metal bump at a bonding portion with the resonator element is 491 μm²or more and 4007 μm² or less.

### BRIEF DESCRIPTION OF THE DRAWINGS

FIG. 1 is a perspective view of a resonator device according to Embodiment 1.

FIG. 2 is a plan view of the resonator device.

FIG. 3 is a cross-sectional view taken along a cross-section b-b in FIG. 1.

FIG. 4 is an enlarged view of a portion c in FIG. 3.

FIG. 5 is a perspective view showing a metal bump in an initial state.

FIG. 6 is a graph showing a relationship between a diameter of the metal bump and a shear strength.

FIG. 7 is a table of temperature characteristic first-order coefficients when the diameter of the metal bump is changed, in which a difference from a reference value is shown as change amount data.

FIG. 8 is a graph obtained by converting FIG. 7 into a graph.

FIG. 9 is a graph in which an approximate straight line is obtained by plotting differences of the temperature characteristic first-order coefficient from the reference value as change amounts of three metal bumps having different diameters.

FIG. 10 is a side view of a stud bump before bonding.

FIG. 11 is a side view of the stud bump after bonding.

FIG. 12 is a flowchart showing a flow of a method for producing a metal bump.

FIG. 13 shows an aspect of a production process of the metal bump.

FIG. 14 shows an aspect of the production process of the metal bump.

FIG. 15 shows an aspect of the production process of the metal bump.

FIG. 16 is a schematic configuration diagram of a metal bump bonding apparatus.

FIG. 17 is an enlarged view of a surrounding area of a metal bump according to Embodiment 2.

FIG. 18 is an enlarged view of a surrounding area of a metal bump in a different form.

### DESCRIPTION OF EMBODIMENTS

### Embodiment 1

### Configuration of Resonator Device

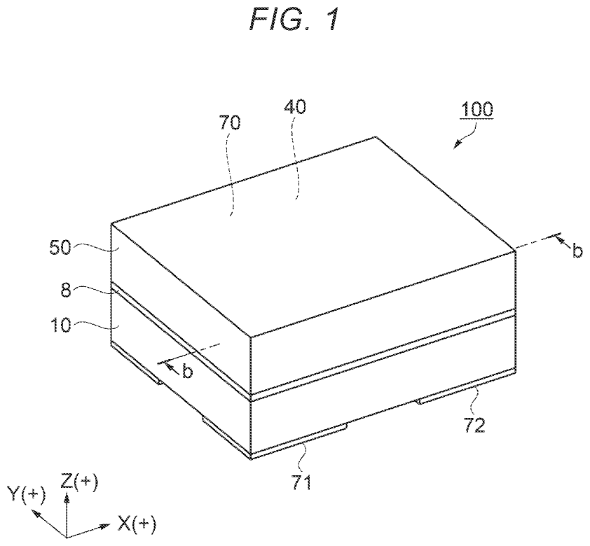

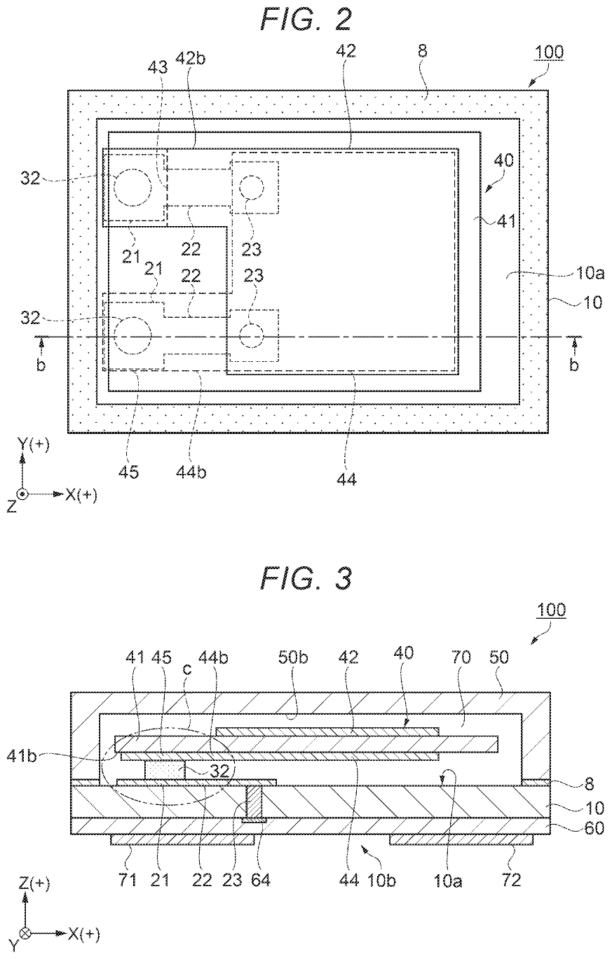

FIG. 1 is a perspective view of a resonator device. FIG. 2 is a plan view of the resonator device. FIG. 3 is a cross-sectional view taken along a cross-section b-b in FIG. 1.

As shown in FIG. 1, a resonator device 100 according to the present embodiment is a box-shaped surface-mounting device that is substantially rectangular in a plan view and that is an oscillator including a base substrate 10, a lid body 50, and the like.

In the drawings, an X-axis, a Y-axis, and a Z-axis are shown as three axes orthogonal to one another. In the embodiment, an extension direction of a long side of the rectangular resonator device 100 is an X-plus direction, an extension direction of a short side is a Y-plus direction, and a thickness direction of the resonator device 100 is a Z-plus direction. The Z-plus direction is also referred to as an upper side, and a Z-minus direction is also referred to as a lower side. The X-plus direction and an X-minus direction are also collectively referred to as an X-axis direction. The same applies to the Y-axis and the Z-axis.

As shown in FIG. 3, the resonator device 100 includes the base substrate 10, a resonator element 40 placed on a first surface 10a of the base substrate 10, and the lid body 50 that covers the resonator element 40 and that is bonded to an upper surface of the base substrate 10.

In a preferred example, the base substrate 10 is a silicon substrate. The base substrate is not limited to the silicon substrate and may also be a semiconductor substrate or an insulating substrate such as a ceramic substrate. As the semiconductor substrate, for example, a substrate of Ge, GaP, GaAs, or InP may be used as the base substrate 10.

On a second surface 10b of the base substrate 10, an integrated circuit portion 60 is provided. The integrated circuit portion 60 is an integrated circuit region that is formed by a semiconductor process on a second surface 10b side of the base substrate 10 and that includes an active element such as a transistor and a passive element such as a capacitor and a resistor. The integrated circuit portion 60 includes an oscillation circuit that oscillates the resonator element 40 to generate an output signal of a predetermined frequency. The first surface 10a and the second surface 10b are in a front-to-back relationship.

In other words, the base substrate 10 is a semiconductor substrate that includes, on a back surface thereof, the integrated circuit portion 60 including the oscillation circuit whereas the resonator element 40 is mounted on a front surface thereof.

FIG. 2 is a plan view of the resonator device 100, in which the lid body 50 is removed for convenience of description.

In a preferred example, the resonator element 40 includes a substantially rectangular resonator substrate 41 implemented by an AT cut quartz crystal substrate having a thickness-shear resonance mode. Since the AT cut quartz crystal substrate has a third-order frequency-temperature characteristic, the resonator element 40 has an excellent temperature characteristic. The resonator substrate 41 is not limited to using the AT cut quartz crystal substrate and, for example, may also be formed of an X cut quartz crystal substrate, a Y cut quartz crystal substrate, a Z cut quartz crystal substrate, a BT cut quartz crystal substrate, an SC cut quartz crystal substrate, or an ST cut quartz crystal substrate.

A constituent material of the resonator substrate 41 is not limited to quartz crystal and may be a piezoelectric single crystal body such as lithium niobate, lithium tantalate, lithium tetraborate, langasite, potassium niobate, and gallium phosphate, or may be a piezoelectric single crystal body other than these described above. In addition, the resonator element 40 is not limited to a piezoelectric drive type resonator element and may also be an electrostatic drive type resonator element using an electrostatic force.

As shown in FIG. 3, a first excitation electrode 42 is provided on a lid body 50 side of the resonator substrate 41. A second excitation electrode 44 is provided on a base substrate 10 side of the resonator substrate 41.

As shown in FIG. 2, the first excitation electrode 42 is an electrode having a rectangular shape in a plan view, an end portion 42b thereof extends to one end of the resonator substrate 41 in the X-minus direction and is folded back to a back side of the resonator substrate 41. A folded portion of the end portion 42b is an electrode terminal 43. The electrode terminal 43 is disposed at a position facing a mounting terminal 21 of the base substrate 10.

A surface of the resonator substrate 41 on the base substrate 10 side is referred to as a facing surface 41b.

The second excitation electrode 44 is a rectangular electrode facing the first excitation electrode 42 with the resonator substrate 41 interposed therebetween. An end portion 44b of the second excitation electrode 44 extends to a one end side of the resonator substrate 41 in the X-minus direction, and a portion facing the mounting terminal 21 of the base substrate 10 is an electrode terminal 45.

Two substantially square mounting terminals 21 are provided on the base substrate 10. The two mounting terminals 21 are spaced apart in the Y-axis direction.

The electrode terminal 43 is disposed at a position overlapping the mounting terminal 21 on a Y-plus side. The electrode terminal 45 is disposed at a position overlapping the mounting terminal 21 on a Y-minus side.

The first excitation electrode 42 and the second excitation electrode 44 are each formed by laminating an underlayer and an upper layer on an uppermost surface. In a preferred example, a main component of the underlayer is a simple substance such as chromium or nickel, or a mixture or an alloy containing chromium or nickel, and a main component of the upper layer is gold (Au). The same applies to the electrode terminals 43 and 45. The main component of the underlayer is not limited thereto and may be any material having adhesion to the resonator substrate 41, specifically, may be a metal material such as chromium (Cr), nickel (Ni), titanium (Ti), tungsten (W), silver (Ag), or aluminum (Al), or an alloy containing such a metal material. The main component of the upper layer is not limited to gold and may be a material having particularly high electrical conductivity, specifically, may be a metal material, for example, a precious metal element such as silver (Ag), platinum (Pt), palladium (Pd), or iridium (Ir), or an alloy containing such a metal material.

As shown in FIG. 3, the electrode terminal 45 is coupled to the mounting terminal 21 of the base substrate 10 via a metal bump 32. In other words, the second excitation electrode 44 is electrically coupled to the corresponding mounting terminal 21 via the metal bump 32. Similarly, the first excitation electrode 42 is also electrically coupled to the corresponding mounting terminal 21 via the metal bump 32.

In a preferred example, the metal bump 32 is a gold bump. The metal bump 32 is not limited to the gold bump as long as the metal bump 32 has both electrical conductivity and a bonding property, and for example, various electrically conductive bumps such as a silver bump, a copper bump, a solder bump, and a resin core bump may be used as the metal bump 32.

As shown in FIG. 3, the mounting terminal 21 is electrically coupled to a through electrode 23 via a wiring portion 22. Similarly, the mounting terminal 21 corresponding to the first excitation electrode 42 is also electrically coupled to the corresponding through electrode 23 via the wiring portion 22.

A pad 64 is provided at another end below the through electrode 23 and is electrically coupled to the oscillation circuit of the integrated circuit portion 60. Thus, the second excitation electrode 44 of the resonator element 40 and the oscillation circuit of the integrated circuit portion 60 are electrically coupled via the through electrode 23. Similarly, the first excitation electrode 42 of the resonator element 40 and the oscillation circuit of the integrated circuit portion 60 are electrically coupled via the corresponding through electrode 23.

External coupling terminals 71 and 72 are provided on a lower side of the integrated circuit portion 60 of the base substrate 10 via an insulating layer. The external coupling terminals 71 and 72 are electrically coupled to the integrated circuit portion 60. The external coupling terminals 71 and 72 are mounting terminals for surface-mounting the resonator device 100. Although the external coupling terminals 71 and 72 are shown in FIG. 3, external coupling terminals are further provided in reality. Specifically, the external coupling terminals include a plurality of external coupling terminals including a power supply terminal that includes VDD and GND, an oscillation output terminal, and a mode switching signal input terminal.

The lid body 50 is a lid and has a rectangular tray shape in a plan view. As shown cross-sectionally in FIG. 3, a peripheral edge portion of the lid body 50 is bonded to the base substrate 10 in a state in which a recess 50b faces downward in the tray shape. As a preferred example, silicon is adopted as a material of the lid body 50. More specifically, a silicon substrate is wet-etched or dry-etched to form the recess 50b, thereby forming the lid body 50. The material of the lid body 50 is not limited to silicon, and a semiconductor substrate made of a semiconductor material other than silicon may also be used. The material of the lid body 50 May also be a metal such as alloy 42, aluminum, copper, or duralumin, or an alloy containing any of these described other than the semiconductor material.

The lid body 50 is bonded to the base substrate 10 via a bonding material 8. In a preferred example, gold is used as the bonding material 8, and the base substrate 10 and the lid body 50 are bonded by thermocompression bonding of gold. The bonding material 8 is not limited to gold and may be any metal or alloy that enables diffusion bonding between the bonding material 8 and the base substrate 10 and between the bonding material 8 and the lid body 50 and that can ensure electrical conduction between the base substrate 10 and the lid body 50. A method for bonding the lid body 50 and the base substrate 10 is not limited to thermocompression bonding, and may also be surface activated bonding or metal fusion bonding in which a metal brazing material such as gold-tin (AuSn) serving as the bonding material 8 is melted to perform bonding. In the case of surface activated bonding, the bonding may be performed by surface activated bonding in which plasma is emitted to a surface of gold formed in a bonding region of the lid body 50 and a surface of gold formed in a bonding region of the base substrate 10 and the surface-activated gold surfaces are brought into contact with each other to be bonded.

An airtight accommodation space 70 is formed by the base substrate 10 and the lid body 50. The resonator element 40 is accommodated in the accommodation space 70 in a state of being supported in a cantilever manner by a pair of the metal bumps 32. In a preferred example, the accommodation space 70 is hermetically sealed in a depressurized state. The inside of the accommodation space 70 may be hermetically sealed in an inert gas atmosphere.

In other words, in the resonator device 100, the base substrate 10 includes the integrated circuit portion 60 including the oscillation circuit, and further includes the lid body 50 that is bonded to the first surface 10a of the base substrate 10 and that accommodates the resonator element 40 in the accommodation space 70 between the lid body 50 and the base substrate 10.

### Configuration of Metal Bump

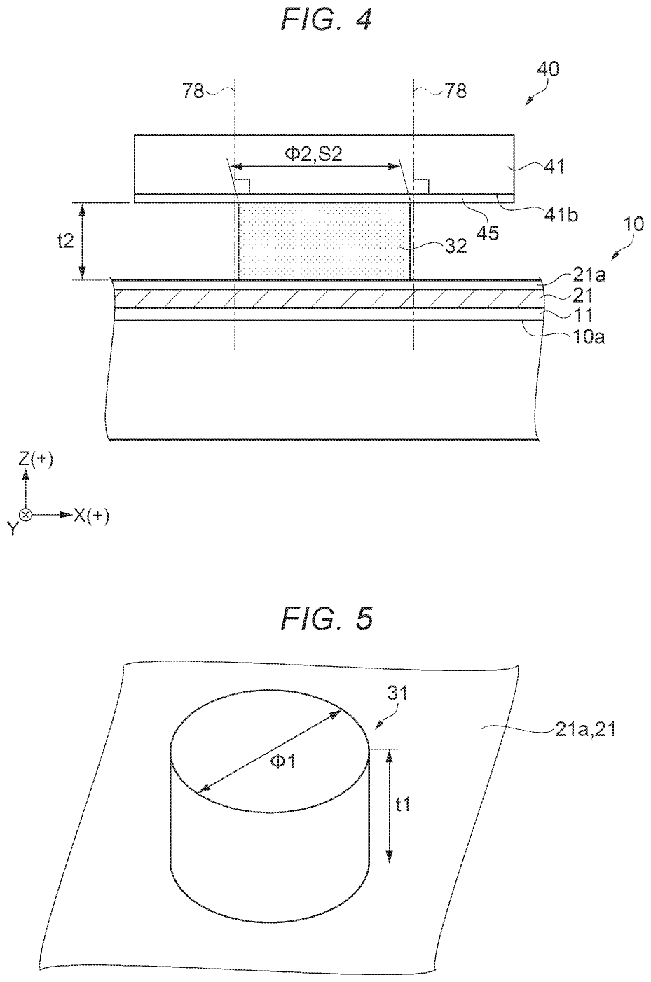

FIG. 4 is an enlarged view of a portion c in FIG. 3. FIG. 5 is a perspective view showing the metal bump in an initial state.

FIG. 4 is an enlarged view of a surrounding area of the metal bump 32 in a bonded state. The metal bump 32 shown in FIG. 4 shows a state of being bonded to the electrode terminal 45 by metal-to-metal diffusion bonding by heating a metal bump 31 in the initial state shown in FIG. 5 and compressing the metal bump 31 under pressure between the resonator element 40 and the base substrate 10.

First, an insulating layer 11 is provided on the first surface 10a of the base substrate 10. In a preferred example, the insulating layer 11 is a SiO₂ layer. In the preferred example, the insulating layer 11 formed of the SiO₂ layer is formed by thermally oxidizing the base substrate 10. A method for forming the SiO₂ layer is not limited to the formation method by thermal oxidation, and the SiO₂ layer may also be formed by chemical vapor deposition (CVD) serving as a chemical vapor deposition method.

The mounting terminal 21 is provided on the insulating layer 11. In a preferred example, the mounting terminal 21 is an electrically conductive layer in which a plurality of metal layers are laminated. An outermost layer 21a formed of an Au layer is provided at a surface of the mounting terminal 21. Hereinafter, the mounting terminal 21 will be described as including the outermost layer 21a. The plurality of metal layers are, for example, a TiW layer, a Cu layer, a Ti layer, and an Au layer. The disclosure is not limited to such a configuration as long as the outermost layer 21a of the mounting terminal 21 is an Au layer. When a Cu layer is contained, it is preferable to provide a metal barrier layer between the Cu layer and the Au layer in order to prevent diffusion caused by contact therebetween. As a method for forming the plurality of metal layers, for example, a known film-forming method such as a sputtering method or a plating method can be used.

As described above, the electrode terminal 45 is an Au layer made of gold in the preferred example. The same applies to the electrode terminal 43.

As shown in FIG. 4, the metal bump 32 is provided in a flat cylindrical shape between the mounting terminal 21 and the electrode terminal 45. A diameter of the metal bump 32 is a diameter φ2, a cross-sectional area of a bonding portion thereof with the electrode terminal 45 is an area S2, and a height of the metal bump 32 is a height t2. The diameter φ2 of the metal bump 32 is a diameter of an end surface of the metal bump 32 adjacent to the resonator element 40 in a bonded state after the resonator element 40 and the base substrate 10 are bonded to each other by the metal bump 31. The cross-sectional area S2 of the bonding portion with the electrode terminal 45 is a cross-sectional area of the end surface of the metal bump 32 adjacent to the resonator element 40 in the bonded state after the resonator element 40 and the base substrate 10 are bonded to each other by the metal bump 31.

As shown in FIG. 4, a side surface of the metal bump 32 is provided along a virtual line 78. The virtual line 78 is a line segment perpendicular to the facing surface 41b of the resonator substrate 41. In other words, in a cross-section perpendicular to the facing surface 41b of the resonator substrate 41 facing the base substrate 10, the side surface of the metal bump 32 is provided along the virtual line 78 perpendicular to the facing surface 41b of the resonator substrate 41. The side surface of the metal bump 32 is perpendicular to the facing surface 41b of the resonator substrate 41 facing the base substrate 10.

In other words, the resonator device 100 includes the base substrate 10 having the first surface 10a and the second surface 10b in a front-to-back relationship with the first surface 10a, the resonator element 40 located on the first surface 10a side of the base substrate 10 and including the resonator substrate 41 and the electrode terminal 45 disposed at the facing surface 41b of the resonator substrate 41 facing the base substrate 10, the mounting terminal 21 disposed at the first surface 10a, and the metal bump 32 disposed between the base substrate 10 and the resonator element 40, the metal bump 32 being configured to bond the base substrate 10 and the resonator element 40 and electrically couple the mounting terminal 21 and the electrode terminal 45.

### Optimal Size of Metal Bump

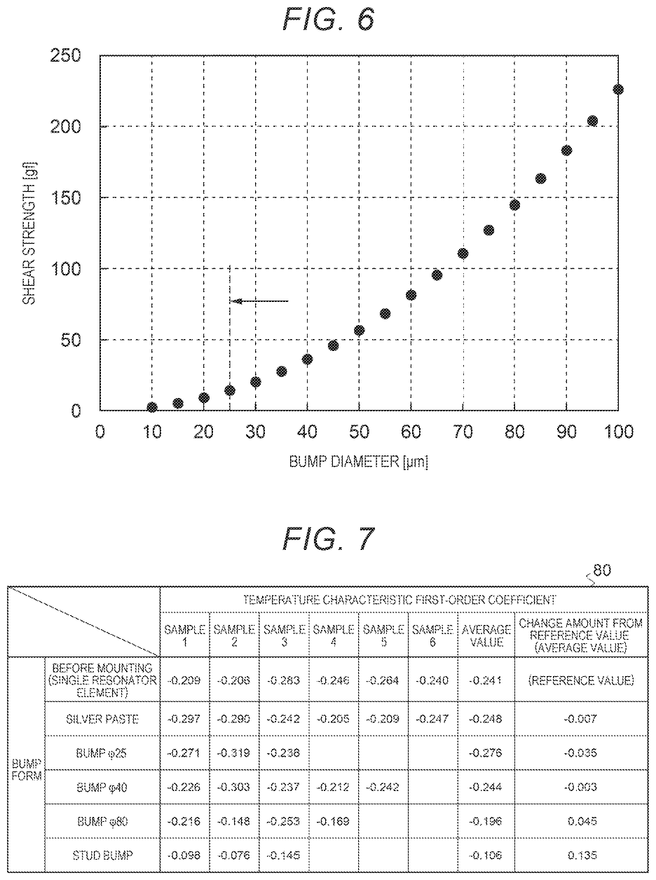

FIG. 6 is a graph showing a relationship between the diameter of the metal bump and a shear strength, in which a horizontal axis represents the diameter φ2 (μm) of the metal bump 32, and a vertical axis represents the shear strength (gf) of the metal bump 32 in the Y-axis direction.

In FIG. 6, a peak value of the shear strength, which is a breaking strength when a load is applied to the metal bump 32 in the Y-plus direction with a shear jig, is plotted. As shown in FIG. 6, it is indicated that the diameter φ2 of the metal bump 32 and the shear strength serving as an index of a mounting strength are in a substantially proportional relationship.

Here, one of the metal bumps 32 bonding the resonator element 40 to the base substrate 10 is required to have a shear strength of 14 gf or more in view of a size of the resonator element 40 to be mounted. Thus, the diameter φ2 of the metal bump 32 is preferably 25 μm or more.

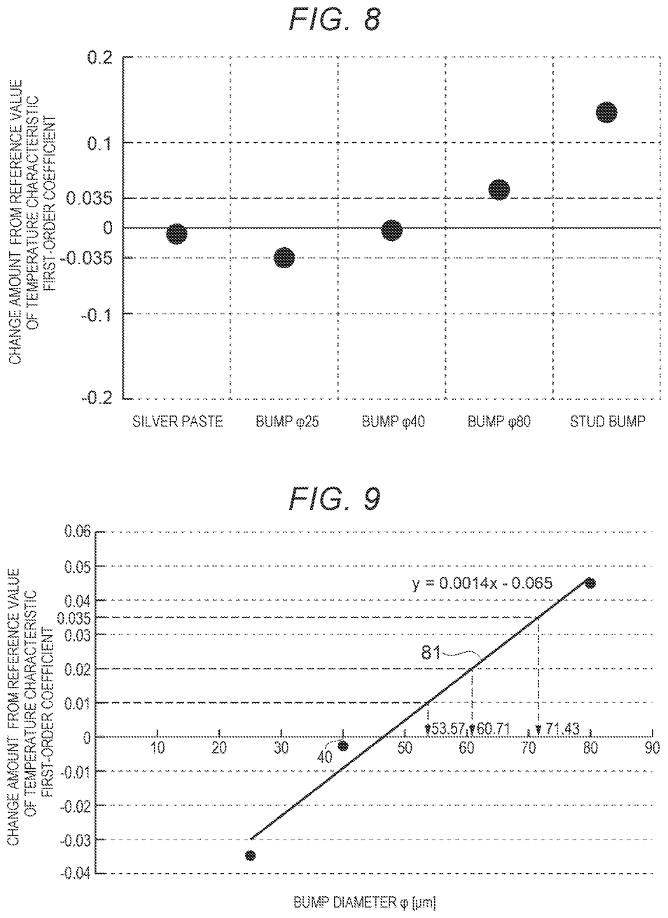

FIG. 7 is a table of temperature characteristic first-order coefficients when the diameter of the metal bump is changed, in which a difference from a reference value is shown as change amount data. The reference value is a temperature characteristic first-order coefficient of a single resonator element, that is, a temperature characteristic gradient. As a comparative example, change amounts of a silver paste and a stud bump are also calculated. FIG. 8 is a graph obtained by converting FIG. 7 into a graph, in which a horizontal axis represents a bump type and a vertical axis represents a change amount from the reference value of the temperature characteristic first-order coefficient.

First, as the reference value, the single resonator element 40 before being mounted is set in a dedicated measurement jig, and a first-order coefficient representing the temperature characteristic gradient is measured. As shown in a table 80 in FIG. 7, the number of samples is 6, and an average value of first-order coefficients is “−0.241”. Thereafter, the average value “−0.241” of the first-order coefficients of the single resonator element 40 before mounting is set as the reference value, and it is determined that an influence on a temperature characteristic due to mounting decreases as a difference (change amount) from the reference value decreases.

In a case where the diameter φ2 of the metal bump 32 is 25 μm, the resonator device 100 in a state in which the resonator element 40 is mounted using the bump is prepared, and the temperature characteristic first-order coefficient is measured. The number of samples is 3, and an average value of first-order coefficients is “−0.276”.

Similarly, in a case where the diameter φ2 of the metal bump 32 is 40 μm, the resonator device 100 in a state in which the resonator element 40 is mounted using the bump is also prepared, and the temperature characteristic first-order coefficient is also measured. The number of samples is 5, and the average value of the first-order coefficients is “−0.244”.

Similarly, in a case where the diameter φ2 of the metal bump 32 is 80 μm, the resonator device 100 in a state in which the resonator element 40 is mounted using the bump is also prepared, and the temperature characteristic first-order coefficient is also measured. The number of samples is 4, and the average value of the first-order coefficients is “−0.196”.

As a comparative example, the resonator device 100 in a state in which the resonator element 40 is mounted using the silver paste instead of the metal bump is prepared, and the temperature characteristic first-order coefficient is measured. The number of samples is 6, and the average value of the first-order coefficients is “−0.248”.

Similarly, as another comparative example, the resonator device 100 in a state in which the resonator element 40 is mounted using the gold stud bump instead of the metal bump is prepared, and the temperature characteristic first-order coefficient is measured. The number of samples is 3, and the average value of the first-order coefficients is “−0.106”.

FIG. 8 is a graph in which a difference between the temperature characteristic first-order coefficient of each bump form described above and the reference value based on the single resonator element before mounting is plotted as the change amount, a horizontal axis represents the diameter of the metal bump (μm), and a vertical axis represents the change amount from the reference value of the temperature characteristic first-order coefficient. In view of required performance of the resonator device 100, the change amount of the first-order coefficient is required to be within “±0.035”. This value is referred to as a change amount allowable range or an allowable range.

As shown in FIG. 8, when the diameter φ2 of the metal bump 32 is 80 μm, it is indicated that the change amount of the first-order coefficient is “0.045”, which exceeds the above range. In the case of the stud bump, it is indicated that the change amount of the first-order coefficient is “0.135”, which exceeds the allowable range.

On the other hand, when the diameter φ2 of the metal bump 32 is φ25 μm, it is indicated that the change amount of the first-order coefficient is “−0.035”, which is within the allowable range.

The silver paste in the comparative example has the change amount of the first-order coefficient within the allowable range, but has a larger wetting spread and is more difficult to be reduced in size as compared with the metal bump 32. In addition, since the paste contains a solvent, there are inherent problems such as generation of gas.

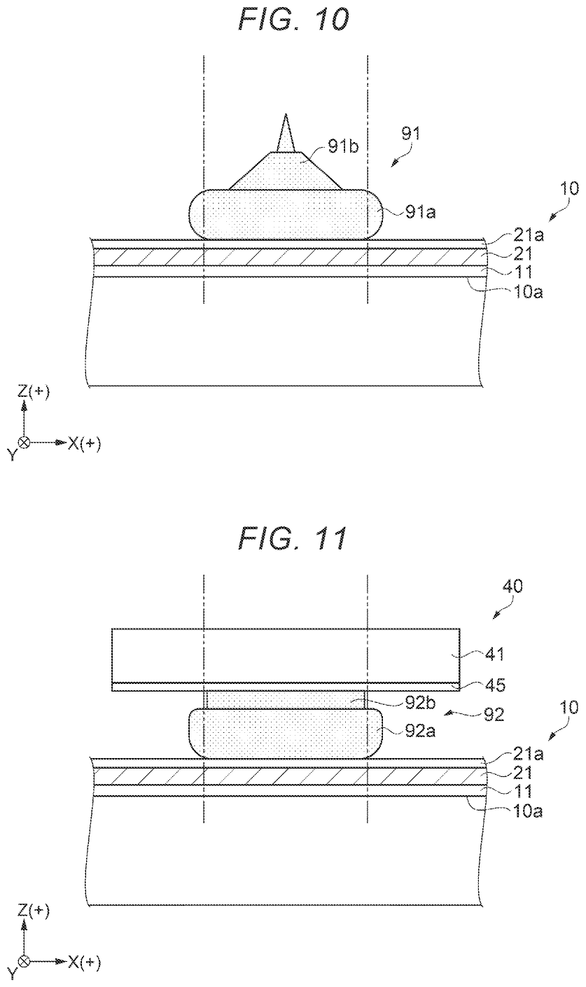

FIG. 10 is a side view of the stud bump before bonding, which corresponds to FIG. 5. FIG. 11 is a side view of the stud bump after bonding, which corresponds to FIG. 4.

As shown in FIG. 10, a stud bump 91 before bonding has a configuration in which a two-stage conical-shaped protrusion 91b is provided on a circular plate-shaped base portion 91a. This is because the stud bump 91 is formed by feeding out a gold wire from a capillary of a bonding apparatus, forming a tip of the gold wire into a ball shape by discharge melting, then bonding the tip to the base substrate 10, and cutting the gold wire.

A stud bump 92 in FIG. 11 shows a state after the resonator element 40 is bonded using the stud bump 91. As shown in FIG. 11, the stud bump 92 after bonding has a shape in which an upper portion 92b slightly thinner than a base portion 92a is provided on the base portion 92a having a circular plate shape. Since the upper portion 92b is a portion where the protrusion 91b of the stud bump 91 is crushed, a shape of a bonding portion is not constant, and there is a concern that stress may be applied to the resonator element 40 during bonding, resulting in distortion, which may affect resonance characteristics.

FIG. 9 is a graph in which an approximate straight line is obtained by plotting differences of the temperature characteristic first-order coefficient from the reference value as change amounts of three metal bumps having different diameters, a horizontal axis represents the diameter of the metal bump (μm), and a vertical axis represents the change amount from the reference value of the temperature characteristic first-order coefficient.

A graph 81 in FIG. 9 is an approximate straight line obtained by plotting change amounts from the reference value of the temperature characteristic first-order coefficient at three points where the diameter φ2 of the metal bump 32 is 25 μm, 40 μm, and 80 μm, respectively, and obtaining the approximate straight line from the three points.

As described above, the allowable range of the change amount is within “±0.035”.

In the graph 81, the diameter φ2 of the metal bump 32 corresponding to an upper limit of the change amount “+0.035” is 71.43 μm, which corresponds to the area S2 of 4007 μm².

On the other hand, the diameter φ2 of the metal bump 32 corresponding to a lower limit of the change amount “−0.035” is 25 μm as shown in the table 80, which corresponds to the area S2 of 491 μm². As described above, from the viewpoint of the mounting strength (shear strength), the diameter φ2 of the metal bump 32 is preferably 25 μm or more.

Thus, it is preferable that the area S2, which is the cross-sectional area of the bonding portion of the metal bump 32 with the resonator element 40, is 491 μm² or more and 4007 μm² or less. When converted into the diameter, the diameter φ2 of the metal bump 32 is preferably 25 μm or more and 71.43 μm or less.

The area S2 of the metal bump 32 is preferably 707 μm² or more and 4007 μm² or less. Accordingly, the mounting strength can be improved. In other words, it is preferable that the metal bump 32 has a cylindrical shape, and the diameter φ2 of the metal bump 32 is 30 μm or more and 71.43 μm or less.

The area S2 of the metal bump 32 is preferably 962 μm² or more and 4007 μm² or less. Accordingly, the mounting strength can be further improved. In other words, it is preferable that the metal bump 32 has a cylindrical shape, and the diameter φ2 of the metal bump 32 is 35 μm or more and 71.43 μm or less.

In the graph 81, the diameter φ2 of the metal bump 32 corresponding to the change amount “+0.02” is 60.71 μm, which corresponds to the area S2 of 2895 μm².

Therefore, the area S2 of the metal bump 32 is preferably 491 μm² or more and 2895 μm² or less. Accordingly, the temperature characteristic can be improved. In other words, it is preferable that the metal bump 32 has a cylindrical shape, and the diameter φ2 of the metal bump 32 is 25 μm or more and 60.71 μm or less.

The area S2 of the metal bump 32 is preferably 707 μm² or more and 2895 μm² or less. Accordingly, the mounting strength and the temperature characteristic can be improved. In other words, it is preferable that the metal bump 32 has a cylindrical shape, and the diameter φ2 of the metal bump 32 is 30 μm or more and 60.71 μm or less.

The area S2 of the metal bump 32 is preferably 962 μm² or more and 2895 μm² or less. Accordingly, the mounting strength and the temperature characteristic can be further improved. In other words, it is preferable that the metal bump 32 has a cylindrical shape, and the diameter φ2 of the metal bump 32 is 35 μm or more and 60.71 μm or less.

In the graph 81, the diameter φ2 of the metal bump 32 corresponding to the change amount “+0.01” is 53.57 μm, which corresponds to the area S2 of 2254μm².

Therefore, the area S2 of the metal bump 32 is preferably 491 μm² or more and 2254 μm² or less. Accordingly, the temperature characteristic can be improved. In other words, it is preferable that the metal bump 32 has a cylindrical shape, and the diameter φ2 of the metal bump 32 is 25 μm or more and 53.57 μm or less.

The area S2 of the metal bump 32 is preferably 707 μm² or more and 2254 μm² or less. Accordingly, the mounting strength and the temperature characteristic can be improved. In other words, it is preferable that the metal bump 32 has a cylindrical shape, and the diameter φ2 of the metal bump 32 is 30 μm or more and 53.57 μm or less.

The area S2 of the metal bump 32 is preferably 962 μm² or more and 2254 μm² or less. Accordingly, the mounting strength and the temperature characteristic can be further improved. In other words, it is preferable that the metal bump 32 has a cylindrical shape, and the diameter φ2 of the metal bump 32 is 35 μm or more and 53.57 μm or less.

### Method for Producing Metal Bump

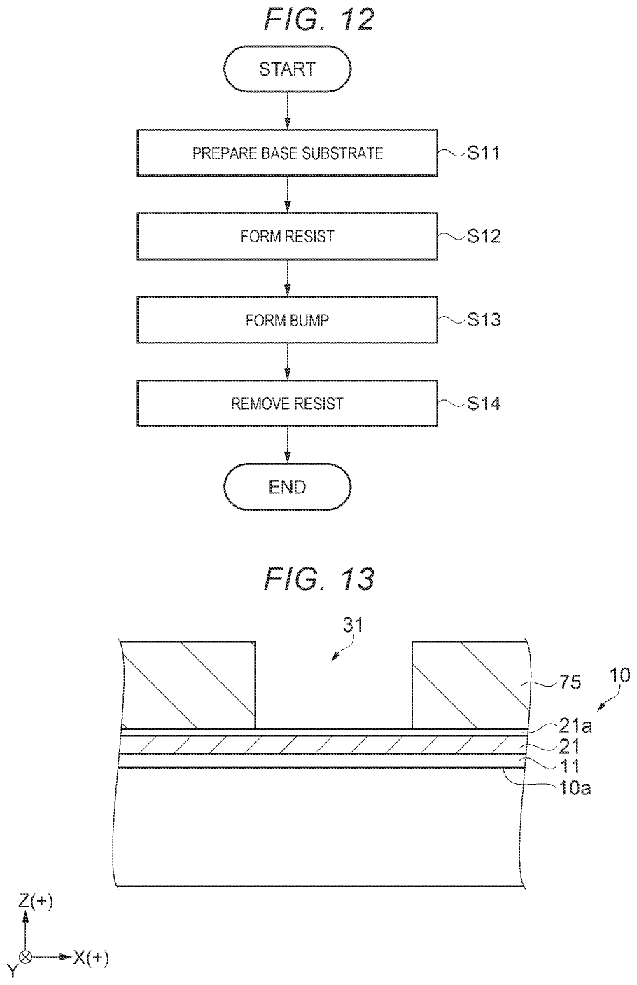

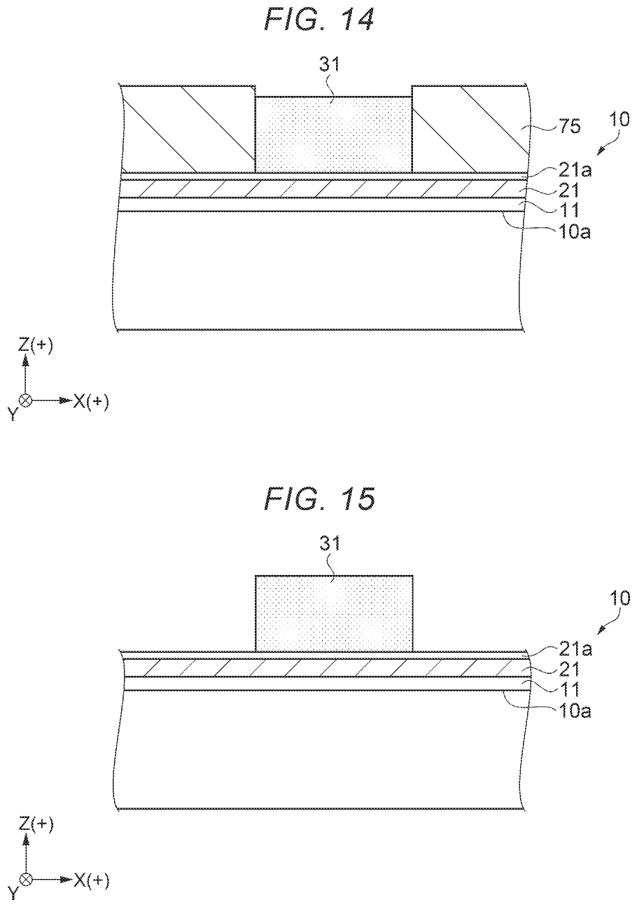

FIG. 12 is a flowchart showing a flow of a method for producing a metal bump. FIGS. 13 to 15 show an aspect of a production process of the metal bump.

Here, the method for producing the metal bump 31 will be described mainly with reference to FIG. 12 and appropriately with reference to the other drawings.

In step S11, the base substrate 10 in a state in which the mounting terminal 21 is formed on the first surface 10a is prepared.

In step S12, a resist 75 in which a portion to be the metal bump 31 is opened is formed on the base substrate 10. FIG. 13 shows this state. The Au layer of the outermost layer 21a of the mounting terminal 21 is exposed to the opening in the resist 75.

In step S13, Au plating is performed in the opening in the resist 75. In a preferred example, the base substrate 10 is immersed in a plating solution, and Au plating is grown to a predetermined thickness by an electroless plating method. The plating method is not limited to electroless plating, and electroplating method may also be used.

In step S14, the resist 75 is removed. Accordingly, the metal bump 31 shown in FIG. 15 is formed. In other words, the metal bump 31 is a plated bump.

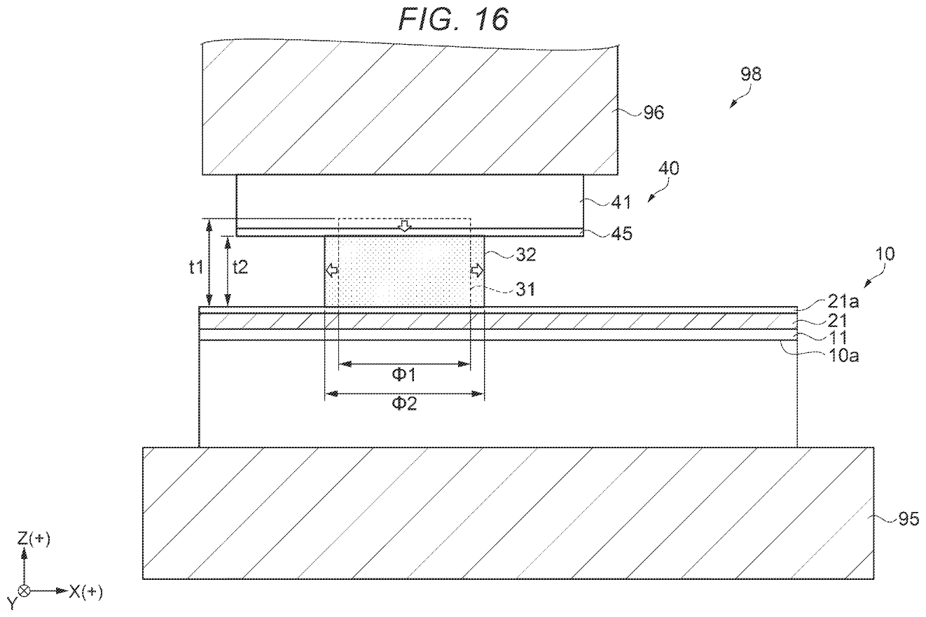

FIG. 16 is a schematic configuration diagram of a metal bump bonding apparatus.

A bonding apparatus 98 includes a heating stage 95 and a bonding tool 96.

As shown in FIG. 16, the base substrate 10 provided with the metal bump 31 is set on the heating stage 95 and heated to, for example, about 150° C. to 220° C.

Then, in a state in which the resonator substrate 41 is placed on the metal bump 31 of the base substrate 10, pressure is applied to the bonding tool 96 from a back surface of the resonator substrate 41 to perform bonding. At this time, an ultrasonic wave may also be applied. Accordingly, the metal bump 31 is heated and compressed, and is bonded to the electrode terminal 45 of the resonator substrate 41 by metal-to-metal diffusion bonding, thereby forming the metal bump 32 shown in FIG. 16.

When a height of the metal bump 31 before bonding is a height t1 and a diameter thereof is a diameter φ1, the height of the metal bump 32 after bonding is the height t2, which is lower than the height t1, and the diameter thereof is the diameter φ2, which is larger than the diameter φ1. For example, when the height t1 of the metal bump 31 before bonding is 15 μm and the diameter φ1 is 38 μm, the height t2 of the metal bump 32 after bonding is 10 μm and the diameter φ2 is 47 μm. When the height t1 of the metal bump 31 before bonding is 20 μm and the diameter φ1 is 55 μm, the height t2 of the metal bump 32 after bonding is 15 μm and the diameter φ2 is 65 μm.

Thus, the height t1 of the metal bump 31 before bonding is preferably 25 μm or less, and more preferably 7 μm or more and 17 μm or less, from the viewpoint of shape stabilization after bonding. In other words, the height t1 of the metal bump 31, which is a length in a direction orthogonal to the first surface 10a of the base substrate 10, is preferably 25 μm or less.

In the above description, a planar shape of the metal bump 32 is a circle, but is not limited thereto, and may also be an ellipse or a polygon such as a triangle, a rectangle, or a hexagon. In addition, according to the above production method, one metal bump can be formed of a plurality of small bumps.

As described above, according to the resonator device 100 in the present embodiment, the following effects can be attained.

The resonator device 100 includes the base substrate 10 having the first surface 10a and the second surface 10b in a front-to-back relationship with the first surface 10a, the resonator element 40 located on the first surface 10a side of the base substrate 10 and including the resonator substrate 41 and the electrode terminal 45 disposed at the facing surface 41b of the resonator substrate 41 facing the base substrate 10, the mounting terminal 21 disposed at the first surface 10a, and the metal bump 31 disposed between the base substrate 10 and the resonator element 40, the metal bump 31 being configured to bond the base substrate 10 and the resonator element 40 and electrically couple the mounting terminal 21 and the electrode terminal 45. The area S2, which is the cross-sectional area of the metal bump 32 at the bonding portion with the resonator element 40, is 491 μm² or more and 4007 μm² or less.

Accordingly, unlike a stud bump in the related art in which a temperature characteristic may decrease since a conical protrusion is crushed at the time of bonding, thereby a shape of a bonding portion is not stable and distortion is generated, by using the metal bump 31 that is cylindrical before bonding, an influence of stress during bonding can be reduced and a bonding area can be increased since deformation caused by bonding is mainly flattening. Thus, a bonding state can be stabilized and desired resonance characteristics can be attained.

Further, unlike a structure in the related art in which a recess is formed in a quartz crystal resonator element, no recess is formed in the resonator element 40, a size of the metal bump 32 is optimized in consideration of the mounting strength and the temperature characteristic, whereby the bonding strength can be ensured and the size can be reduced.

Thus, it is possible to provide the resonator device 100 that has a small size, that ensures the bonding strength, and that has stable resonance characteristics.

The area S2 of the metal bump 32 is preferably 707 μm² or more and 4007 μm² or less.

Accordingly, the bonding strength can be improved.

The area S2 of the metal bump 32 is preferably 962 μm² or more and 4007 μm² or less.

Accordingly, the bonding strength can be further improved.

The area S2 of the metal bump 32 is preferably 491 μm² or more and 2895 μm² or less.

Accordingly, the temperature characteristic can be improved.

The area S2 of the metal bump 32 is preferably 707 μm² or more and 2895 μm² or less.

Accordingly, the bonding strength and the temperature characteristic can be improved.

The area S2 of the metal bump 32 is preferably 962 μm² or more and 2895 μm² or less.

Accordingly, the bonding strength and the temperature characteristic can be further improved.

The area S2 of the metal bump 32 is preferably 491 μm² or more and 2254 μm² or less.

Accordingly, the temperature characteristic can be improved.

The area S2 of the metal bump 32 is preferably 707 μm² or more and 2254 μm² or less.

Accordingly, the bonding strength and the temperature characteristic can be improved.

The area S2 of the metal bump 32 is preferably 962 μm² or more and 2254 μm² or less.

Accordingly, the bonding strength and the temperature characteristic can be further improved.

The height t1 of the metal bump 31, which is the length in the direction orthogonal to the first surface 10a of the base substrate 10, is 25 μm or less.

Accordingly, the shape of the metal bump 32 after bonding can be a flat and stable cylindrical shape.

The side surface of the metal bump 32 is perpendicular to the facing surface 41b of the resonator substrate 41 facing the base substrate 10.

Accordingly, the bonding portion after bonding the resonator element 40 and the metal bump 32 is stabilized, and reliability of the resonance characteristics including the temperature characteristic is improved.

In a cross-section perpendicular to the facing surface 41b of the resonator substrate 41 on the base substrate 10 side, the side surface of the metal bump 32 is provided along the virtual line 78 perpendicular to the facing surface 41b of the resonator substrate 41.

Accordingly, the bonding portion after bonding the resonator element 40 and the metal bump 32 is stabilized, and the reliability of the resonance characteristics including the temperature characteristic is improved.

The metal bump 31 is a plated bump.

Accordingly, the metal bump 31 having a cylindrical shape before bonding can be formed.

The metal bumps 31 and 32 each have a cylindrical shape.

Accordingly, the resonator element 40 can be stably bonded by the cylindrical metal bump 32 having a stable shape.

The metal bump 32 has a cylindrical shape, and the diameter φ2 of the metal bump 32 is 30 μm or more and 71.43 μm or less.

Accordingly, the bonding strength can be ensured, and the resonance characteristics including the temperature characteristic can be stabilized.

The resonator element 40 is a thickness-shear resonator element.

Accordingly, the resonator element 40 having an excellent temperature characteristic can be provided.

The resonator element 40 is a quartz crystal resonator element including the resonator substrate 41 formed of an AT cut quartz crystal substrate.

Accordingly, the resonator element 40 having an excellent temperature characteristic can be provided.

In the resonator device 100, the base substrate 10 includes the integrated circuit portion 60 including the oscillation circuit, and further includes the lid body 50 that is bonded to the first surface 10a of the base substrate 10 and that accomodates the resonator element 40 in the accommodation space 70 between the lid body 50 and the base substrate 10.

Accordingly, it is possible to provide the resonator device 100 that is small in size due to a configuration in which the oscillation circuit is contained in the base substrate 10 and that has stable resonance characteristics since the resonator element 40 is accomodated in the airtight accomodation space 70.

### Embodiment 2

### Different Forms of Terminal Portion

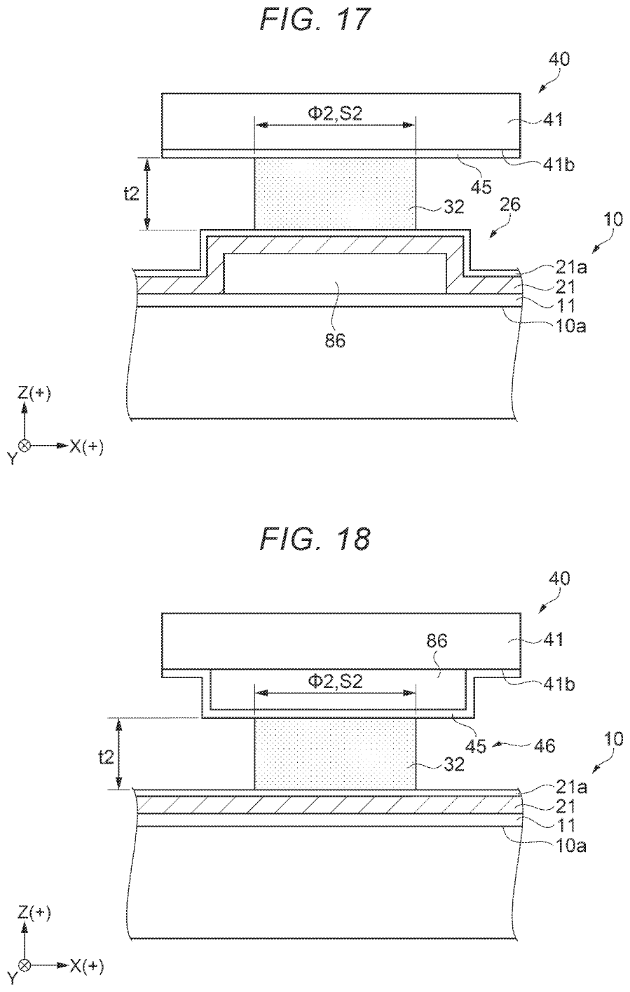

FIG. 17 is an enlarged view of a surrounding area of a metal bump according to Embodiment 2, which corresponds to FIG. 4. FIG. 18 is an enlarged view of a surrounding area of a metal bump in a different form, which corresponds to FIG. 4. In the above embodiment, the mounting terminal 21 has a laminated structure of metal layers including a plurality of metal layers, but the disclosure is not limited thereto, and for example, a low elastic modulus layer such as a resin may be provided. Hereinafter, the same parts as those in the above embodiment are denoted by the same reference numerals, and the redundant description is omitted.

As shown in FIG. 17, in a mounting terminal 26 according to the embodiment, a low elastic modulus layer 86 is provided in a lower layer of the mounting terminal 21. Specifically, in the mounting terminal 26, the low elastic modulus layer 86 is provided on the insulating layer 11 of the base substrate 10, and the mounting terminal 21 is formed thereon. In a preferred example, the low elastic modulus layer 86 is made of a UV-curable photosensitive resin having an elastic modulus smaller than an elastic modulus of the metal bump 32. Accordingly, the low elastic modulus layer 86 can be finely processed using a semiconductor process and can be formed with high accuracy.

A planar size of the low elastic modulus layer 86 is larger than that of the metal bump 32 and can support an entire surface of the metal bump 32 from below. A thickness of the low elastic modulus layer 86 is about 5 μm in a preferred example and is not limited thereto. The thickness may be any thickness at which a stress buffering effect is attained and may be appropriately set according to a weight of the resonator element 40, the size of the metal bump 32, or the like.

The material of the low elastic modulus layer 86 is not limited to the UV-curable photosensitive resin, and any material having an elastic modulus smaller than the elastic modulus of the metal bump 32 may be used, such as a phenol resin, an epoxy resin, or a polyimide resin. An additive such as a metal filler may also be mixed in the low elastic modulus layer 86. In addition, it is sufficient that the low elastic modulus layer 86 is provided inside the mounting terminal 26, and for example, the low elastic modulus layer 86 may be provided between any of the metal layers among the plurality of metal layers constituting the mounting terminal 21.

As shown in FIG. 18, the low elastic modulus layer 86 may also be provided inside an electrode terminal 46 of the resonator element 40. Specifically, in the electrode terminal 46, the low elastic modulus layer 86 is provided between the resonator substrate 41 and the electrode terminal 45. A material, a size, and the like of the low elastic modulus layer 86 are the same as those in the description of the mounting terminal 26 except that the low elastic modulus layer 86 is provided inside the electrode terminal 46.

Although not shown, the metal bump 32 may also be sandwiched between the mounting terminal 26 and the electrode terminal 46. That is, the low elastic modulus layer 86 may be provided at terminals above and below the metal bump 32.

In other words, the low elastic modulus layer 86 having the elastic modulus smaller than that of the metal bump 32 is provided inside at least one of the electrode terminal 46 and the mounting terminal 26.

As described above, according to the resonator device 100 in the present embodiment, the following effects can be attained in addition to the effects of the above-described embodiment.

According to the resonator device 100, the low elastic modulus layer 86 having the elastic modulus smaller than that of the metal bump 32 is provided inside at least one of the electrode terminal 46 and the mounting terminal 26.

Accordingly, since the low elastic modulus layer 86 is provided between the metal bump 32 and the base substrate 10 and/or the resonator substrate 41, thermal stress and impact are absorbed and relaxed by the low elastic modulus layer 86, and plastic deformation of the metal bump 32 can be prevented. Thus, the resonance characteristics including the temperature characteristic of the resonator element 40 can be stabilized.

Thus, it is possible to provide the resonator device 100 that has a small size, that ensures the bonding strength, and that has stable resonance characteristics.

What is claimed is:

1. A resonator device comprising:
a base substrate having a first surface and a second surface in a front-to-back relationship with the first surface;
a resonator element located on a first surface side of the base substrate and including a resonator substrate and an electrode terminal disposed at a base-substrate-side surface of the resonator substrate;
a mounting terminal disposed at the first surface; and
a metal bump disposed between the base substrate and the resonator element, the metal bump being configured to bond the base substrate and the resonator element and electrically couple the mounting terminal and the electrode terminal, wherein
a cross-sectional area of the metal bump at a bonding portion with the resonator element is 491 μm² or more and 4007 μm² or less.

2. The resonator device according to claim 1, wherein
the cross-sectional area of the metal bump is 707 μm² or more and 4007 μm² or less.

3. The resonator device according to claim 1, wherein
the cross-sectional area of the metal bump is 962 μm² or more and 4007 μm² or less.

4. The resonator device according to claim 1, wherein
the cross-sectional area of the metal bump is 491 μm² or more and 2895 μm² or less.

5. The resonator device according to claim 1, wherein
the cross-sectional area of the metal bump is 707 μm² or more and 2895 μm² or less.

6. The resonator device according to claim 1, wherein
the cross-sectional area of the metal bump is 962 μm² or more and 2895 μm² or less.

7. The resonator device according to claim 1, wherein
the cross-sectional area of the metal bump is 491 μm² or more and 2254 μm² or less.

8. The resonator device according to claim 1, wherein
the cross-sectional area of the metal bump is 707 μm² or more and 2254 μm² or less.

9. The resonator device according to claim 1, wherein
the cross-sectional area of the metal bump is 962 μm² or more and 2254 μm² or less.

10. The resonator device according to claim 1, wherein
the metal bump has a length of 25 μm or less in a direction orthogonal to the first surface.

11. The resonator device according to claim 10, wherein
a side surface of the metal bump is perpendicular to the base-substrate-side surface of the resonator substrate.

12. The resonator device according to claim 10, wherein
in a cross-section perpendicular to the base-substrate-side surface of the resonator substrate, a side surface of the metal bump is along a virtual line perpendicular to the base-substrate-side surface of the resonator substrate.

13. The resonator device according to claim 1, wherein
the metal bump is a plated bump.

14. The resonator device according to claim 13, wherein
the metal bump has a cylindrical shape.

15. The resonator device according to claim 1, wherein
the metal bump has a cylindrical shape, and
a diameter of the metal bump is 30 μm or more and 71.43 μm or less.

16. The resonator device according to claim 1, wherein
in at least one of the electrode terminal and the mounting terminal, a low elastic modulus layer having an elastic modulus lower than that of the metal bump is provided.

17. The resonator device according to claim 1, wherein
the resonator element is a thickness-shear resonator element.

18. The resonator device according to claim 1, wherein
the resonator element is a quartz crystal resonator element including an AT cut quartz crystal substrate.

19. The resonator device according to claim 1, wherein
the base substrate includes an integrated circuit portion that includes an oscillation circuit,
the resonator device further comprising: a lid body bonded to the first surface of the base substrate and configured to accommodate the resonator element in an accommodation space between the lid body and the base substrate.
